(19) United States
(12) Patent Application Publication
(10) Pub. No.: US 2011/0120539 A1
(43) Pub. Date: May 26, 2011

(54) ON-WINDOW SOLAR-CELL HEAT-SPREADER

(75) Inventors: Juan Carlos Miñano, Madrid (ES); Pablo Benitez, Madrid (ES); Julio C. Chaves, Coimbra (PT); Waqidi Falicoff, Stevenson Ranch, CA (US); Yupin Sun, Yorba Linda, CA (US)

(73) Assignee: Light Prescriptions Innovators, LLC, Altadena, CA (US)

(21) Appl. No.: 12/952,826

(22) Filed: Nov. 23, 2010

Related U.S. Application Data
(60) Provisional application No. 61/264,328, filed on Nov. 25, 2009.

(51) Int. Cl. H01L 31/06; H01J 7/24; G01J 1/42; H01L 31/0232

(52) U.S. Cl. 136/255; 250/238; 250/208.2; 136/259

(57) ABSTRACT

An optoelectrical device, which may be a luminaire or a photovoltaic concentrator, has a transparent cover plate. A target with an optoelectrical transducer that produces waste heat in operation is mounted at an inside face of the transparent cover plate. A primary mirror reflects light between being concentrated on the target and passing generally collimated through the cover plate. A heat spreader is in thermal contact with the target. The heat spreader has heat conductors that thermally connect the target with the inside surface of the cover plate. The heat conductors may be arms extending radially outwards, and may be straight, zigzag, or branching. An array of targets may be mounted on a common cover plate, and their heat spreaders may be continuous from target to target.

### CROSS-REFERENCE TO RELATED APPLICATIONS

This application claims benefit of U.S. Provisional Patent Application No. 61/264,328, filed Nov. 25, 2009 by Miñano et al., titled “On-window solar-cell heat spreader,” which is incorporated herein by reference in its entirety.

This application is related to the following patents and patent applications by several of the same inventors, which are incorporated herein by reference in their entirety.

U.S. Pat. No. 6,639,733 “High Efficiency Non-Imaging Optics.”

U.S. Pat. No. 7,460,985 “Three-dimensional simultaneous multiple-surface method and free-form illumination-optics designed therefrom.”

US 2008/0316761 “Free-Form Lenticular Optical Elements and Their Application to Condensers and Headlamps.”

US 2009/0071467 “Multi-junction solar cells with a homogenizer system and coupled non-imaging light concentrator.”

WO 2008/112310 “Optical concentrator, especially for solar photovoltaics.”

WO 2009/099605 “Transparent heat-spreader for optoelectronic applications.”

US 2010/0123954, published May 20, 2010, and U.S. patent application Ser. No. 12/795,912, filed Jun. 8, 2010, and their associated provisional patent applications Nos. 61/115,892, filed Nov. 18, 2008; 61/268,129, filed Jun. 8, 2009; and 61/278,476, filed Oct. 6, 2009, for “Köhler Concentrator Azimuthally Combining Radial-Kohler Sub-Concentrators.”

### FIELD OF THE INVENTION

The present invention relates generally to light concentration and illumination, and more particularly to LEDs, semiconductor lasers, solar cells, and other applications using optics for concentrating or collimating the light such that an optoelectronic device is located at the small aperture of the optics (with light entering or exiting the larger aperture). That happens, for instance, in parabolic mirror configurations where the primary focus is located at the optics aperture, and the optoelectronic device is at the primary focus.

### BACKGROUND OF THE INVENTION

Photovoltaic solar concentrators differ in whether the cells are located at the rear or the front of the system. In the latter situation, which obtains when the cell is at the prime focus of a reflector, heat removal is more difficult than for a rear location. The only way to keep a heat sink from blocking any sunlight is to place it atop the photovoltaic (PV) cell assembly, within the pencil of rays that is already blocked by the cell assembly itself. In this case, however, substantial heat dissipation can then be obtained only if the heat sink is impractically tall and skinny. Such a configuration would be structurally vulnerable and aesthetically unbalanced. Such a front-cell system, using an XR optical design (see U.S. Pat. No. 6,639,733 for a description of an XR optic), was developed by Boeing Phantom Works of California and Light Prescriptions Innovators, LLC of California (LPI), including several of the present inventors, under the Solar American Initiative. A rendering of the XR module from this project can be seen on the LPI website at http[colon]//www[dot]lpi-llc[dot]com/pdf/Boeing %20ICSC5%20poster[dot]pdf, hereinafter identified as “Prototype A”. The heat sink and secondary optic obstruct approximately 5% of the sunlight falling on the module face. FIG. 14 shows that prior-art module, illustrating the considerable size and complexity of the vertical heat sink on that module. Although the thermal performance of this XR system is quite good, the heat sink has disadvantages, including its large size, high cost, and difficulty of sealing.

It is an object of embodiments of the present invention to overcome or mitigate the disadvantages of that prior art by having the heat sink integrated with and inside the transparent front cover. Now the large area of the cover enables it to become the final link of the heat management chain, which also comprises a tessellation of thermally conductive strips bonded to the inside of the cover. These thin strips can also be used to make electrical connections to the device, as well as interconnect it with others in an array. Embodiments have been designed in which the percent obstructed area is very similar (5-7%) to the aforementioned “Prototype A” XR module by Boeing and LPI. This new approach can also be utilized in other applications, for example, in applications that make use of folded optical architectures, wherein a target, which may be a source (LED) or receiver (PV cell) is facing the primary minor and there is a frontal glazing which can be modified to act as the heat sink. Such modifications, for example, may be required to accommodate the glazing's greater thermal expansion.

### SUMMARY OF THE INVENTION

In concentrating and collimating optoelectronic applications, it is in general necessary to extract heat from the target optoelectronic device (e.g., LED, laser, solar cell). For that purpose a metallic heat spreader is usually needed. In the case of a Cassegrain (rear-focus) location, the heat spreader can have radiator fins attached to it to transfer the heat to the ambient environment (usually the atmosphere) behind the primary mirror. The width of the optoelectronic device is typically small compared to that of the aperture (else it would not be a concentrator) but the attached heat sink is not. That is because the area needed to transfer the heat generated at the optoelectronic device to the ambient at a reasonable temperature drop is typically of similar area to the aperture itself. The fins increase the area without too much increasing the heat sink volume, but still the heat sink area is usually comparable to that of the optics aperture.

The present embodiments comprise a special transparent cover across the aperture of a reflective concentrator or collimator, further comprising provision for spreading the heat of the optoelectronic device across the inside of the cover. Once spread, the heat can easily flow through the cover's thickness to the ambient with a reasonable temperature drop even though glass and other commonly used cover materials have relatively low thermal conductivity. This is so because the heat flow area as been increased enough that the cover exhibits a low thermal resistance to the heat flow. A 6 mm thickness of glass will conduct 166 Watts/m² when there is a 1° C. temperature difference from one face to the other of the glass, if the heat is flowing directly through the glass. Thus the 65% heat generation of a high-efficiency solar cell will require a 4° C. difference at one sun (1000 Watts/m²), which is a very small temperature drop.

The special cover is formed by a glass sheet with thin strips of thermally conductive material bonded to it and radially extending outward from the reflector focus, in order to spread the target's heat over the glass cover. This special cover is hereinafter termed the Heat-Spreading Transparent Cover (HSTC). Because the heat must spread laterally over the glass, as well as through it, the average temperature drop from the metal strips to the external atmosphere will be more than the 1° C. per 6 mm thickness as calculated above, and will depend on how far apart the strips are.

The thin thermally conductive strips can be either shallow in depth (less than a mm) or as deep as needed in the direction away from the glass. In the case where they are deep, they can be used as structural supports by attaching them to the surface of the primary mirror as well as to the front cover. In this configuration, however, these strips must follow the flow-lines of both the incoming radiation and that reflected by the mirror. For conventional geometries, the support strips are therefore vertical (perpendicular to the front cover) and radial from the cell.

Additionally, the strips can be electrically conductive, providing vias for a multiplicity of requirements, or can form hollow vias within which separate wiring, electrically insulated from the strips themselves, is run. For example, the strips can be used to connect an array of PV cells in series. Further, the strips can be bonded to the front cover using an adhesive that is reflective to sunlight, to mitigate heat buildup due to absorption. The deep strips can also be highly specularly reflective, to reduce heat buildup but also to redirect grazing incidence rays to the primary mirror or optic, as well as in the reverse direction to the target. These mirrored vertical strips would interfere minimally with the optical workings of the concentrator, since they follow the flow-lines of the incoming radiation.

It is helpful to compare the optical aperture area with the area necessary to extract waste heat to ambient in some typical preferred embodiments.

In most solar applications, the optical aperture area suffices to transfer to ambient (at a reasonable temperature elevation) the waste heat extracted from the optoelectronic device. For instance, the power received by a solar cell in a photovoltaic concentrator is smaller than the power received by a one-sun solar cell with the same area as the concentrator aperture. This is because the optical concentrator does not have a 100% efficiency (a good optical efficiency is 80%) and also because most concentrators cannot send diffuse radiation from the sky to the photovoltaic cell. Diffuse radiation typically accounts for 10-30% of the total radiation received by a flat surface tracking the sun, annually averaged. In a concentrator, most of that lost radiation is reflected out through the aperture, whereas the one-sun cell absorbs most of it.

The heat load at many concentrator cells is even lower for high-efficiency cells (30%, up to 42% efficient), so these cells actually have less of an overall heat load than conventional one-sun cells, which are typically in the range 15-17% efficient. All these factors together can reduce the heat load in the concentrator cell to only about half of the heat load on a conventional one-sun cell with area equaling the area of the concentrator aperture.

Conventional one-sun (no concentration) modules do not need heat sinks. This is because their heat density is low enough to transfer the heat to ambient without a large delta T (typically no more than 25° C. over ambient). The conventional one-sun photovoltaic module usually exchanges heat with the ambient through a conductive rear as well as through the front glass. With both of its faces conducting, its cell-to-ambient delta temperature equals that of a concentrator with high-efficiency cells dissipating heat through only the front face. Thus the concentrator cell will have no more thermal problems than its much larger one-sun equivalent.

A main goal for a photovoltaic concentrator heat sink is to spread the heat generated at the cell over a surface area comparable to that of the aperture. This is because no more area than that of the cover glass is necessary to transfer the heat to the ambient, given the same temperature elevation as one-sun photovoltaic modules. Moreover, the cell efficiencies of present concentrating (multijunction) cells are less temperature dependent than one-sun cells. This allows the cells to operate at a higher temperature without a big penalty.

Photovoltaic concentration modules typically have a large number of cells connected in series. That is because cells under concentration multiply the photocurrent relative to normal sunlight, but the voltage remains similar. The simplest way to increase the voltage is by series-connecting the cells of an array. Achieving a high output voltage (>100 V) improves the efficiency of the power-conditioning electronics, which is usually attached to the output of the photovoltaic module (e.g., an AC/DC converter, or a maximum power point tracker, or both). At the same time it is in general desirable to attach the heat sinks to each other or to a common metal frame or metal housing. Since the heat sinks are metallic, this procedure establishes a common electric potential for all the heat sinks, which must therefore make good thermal contact with the cells while remaining electrically isolated from the cells. That requires the use of a thin layer of electrically-insulating, thermally-conductive material adjacent to the cells, which is a potential source of electrical isolation failures. Embodiments of the present invention also solve this problem in the same way it is solved in conventional one-sun cells, by using the glass cover as the common frame to attach the cells and heat spreaders.

An objective of embodiments of the present invention is to provide adequate heat spreading, over the glass aperture area, for a front-mounted concentrator photovoltaic cell, with minimal sun blockage. Because the cell has better efficiency at lower temperatures, there will be a heat spreader size that gives maximum output, versus anything smaller that does not sufficiently cool the cell or anything larger that blocks too much of the aperture area. The effectiveness of a heat spreader is given by its thermal conductance (Watts per degree above ambient), which is directly proportional to cross-sectional area and thermal conductivity, and inversely proportional to the mean conduction distance. Increasing the width of the strips spreading the heat will improve the spreading but will add more blockage. Increasing the length of the strips increases the heat distribution, until the strips approach the boundaries of the available area of cover glass, but will increase the blockage. Increasing the height or depth of the strips (in the direction away from the transparent cover plate) improves the spreading with very little increase in blockage. Thus the preferred shape of the strips is that of vertical fins with high longitudinal thermal conductance and low sun blockage. Given its high thermal conductivity, the presently preferred material of these embodiments is copper. However, expected future developments in advanced thermal metamaterials may result in more preferable materials becoming available.

The term “vertical” is used to denote the direction perpendicular to the general plane of the cover, or the direction of the parallel rays passing through the cover sheet. Those two directions are usually substantially the same. Where the device is a photovoltaic concentrator, and the parallel rays are incident direct solar radiation, that direction will be towards the sun and not literally vertical.

The approach of the present embodiments is counter-intuitive in that it utilizes a material that is conventionally looked upon as an insulator, namely glass. Since reflector materials are vulnerable to dust and rain, a cover glass becomes the norm, even in embodiments that do not have a refracting element at the wide aperture, with the additional advantage of a flat surface being much easier to clean than a reflector dish. A sealed cover enables a controlled interior air volume to be established, so that the cell can more easily be isolated from humidity.

### BRIEF DESCRIPTION OF THE DRAWINGS

The above and other aspects, features and advantages of the present invention will be apparent from the following more particular description thereof, presented in conjunction with the following drawings wherein:

FIG. 1A is an exploded view of an embodiment of a solar concentrator.

FIG. 1B is a view of the solar concentrator of FIG. 1A, assembled.

FIG. 1C is a temperature contour line plot overlaid onto a cross-sectional view of the concentrator of FIG. 1A.

FIG. 1D shows a temperature contour line plot overlaid onto a plan view of the concentrator of FIG. 1A.

FIG. 2A is an exploded view of an array of concentrators similar to that of FIG. 1A.

FIG. 2B is a view of the array of FIG. 2A, assembled.

FIG. 3A is an exploded view of an off-axis concentrator.

FIG. 3B is a view of the concentrator of FIG. 3A, assembled.

FIG. 4A is an exploded view of a dual off-axis concentrator.

FIG. 4B is a view of the dual concentrator of FIG. 4A from below, assembled.

FIG. 4C is a view of the dual concentrator of FIG. 4A from above, assembled.

FIG. 5A is an exploded view of an array of off-axis concentrators similar to that of FIG. 3.

FIG. 5B is a view of the array of FIG. 5A, assembled.

FIG. 6A is a lateral view from below of a concentrator array comprising both on-axis and dual off-axis concentrators.

FIG. 6B is a lateral view of the array of FIG. 6A from above.

FIG. 7 shows an example of interior conducting and convecting fins within a reflective concentrator.

FIG. 8 shows an alternative version of conducting strips.

FIG. 9 shows an alternative version of conducting fins.

FIG. 10 shows a further version, with slotted fins.

FIG. 11 shows a further version with zigzag fins.

FIG. 12 shows a further version with zigzag strips.

FIG. 13 shows an air flow speed contour line plot overlaid onto a cross-sectional view of the concentrator of FIG. 1A.

FIG. 14 shows a heat sink of the prior art for a front-mounted cell.

### DETAILED DESCRIPTION OF THE PREFERRED EMBODIMENTS

A better understanding of various features and advantages of the present invention will be obtained by reference to the following detailed description of embodiments the invention and accompanying drawings, which set forth illustrative embodiments that utilize particular principles of the invention.

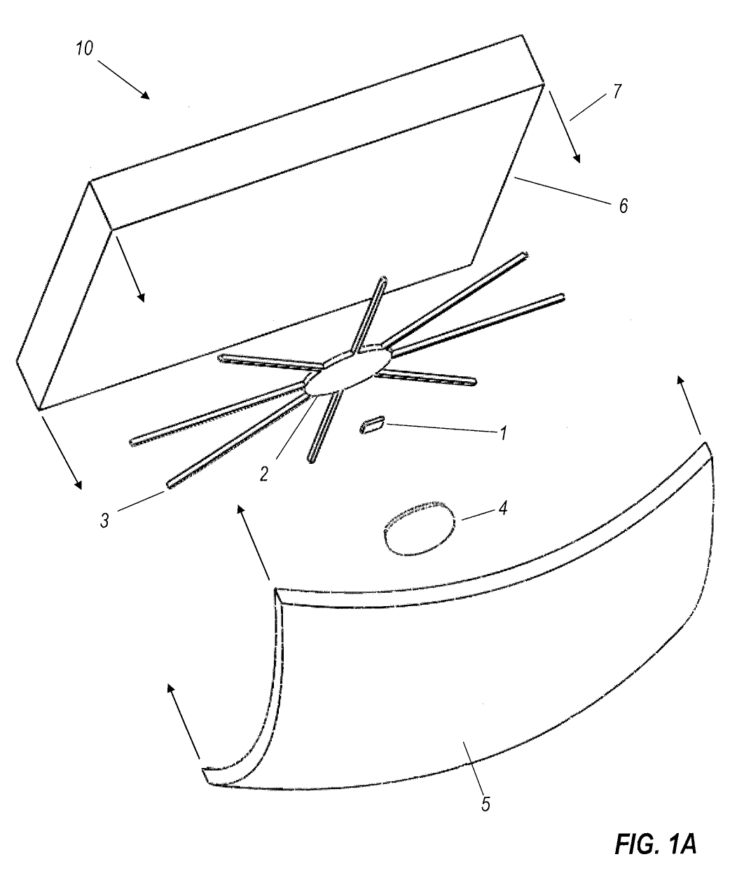

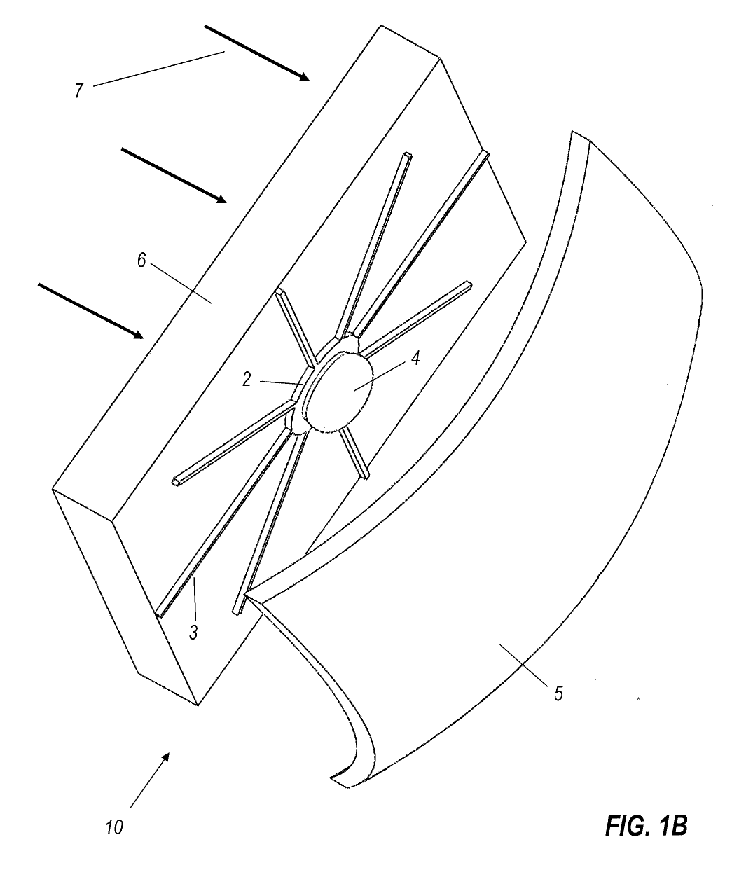

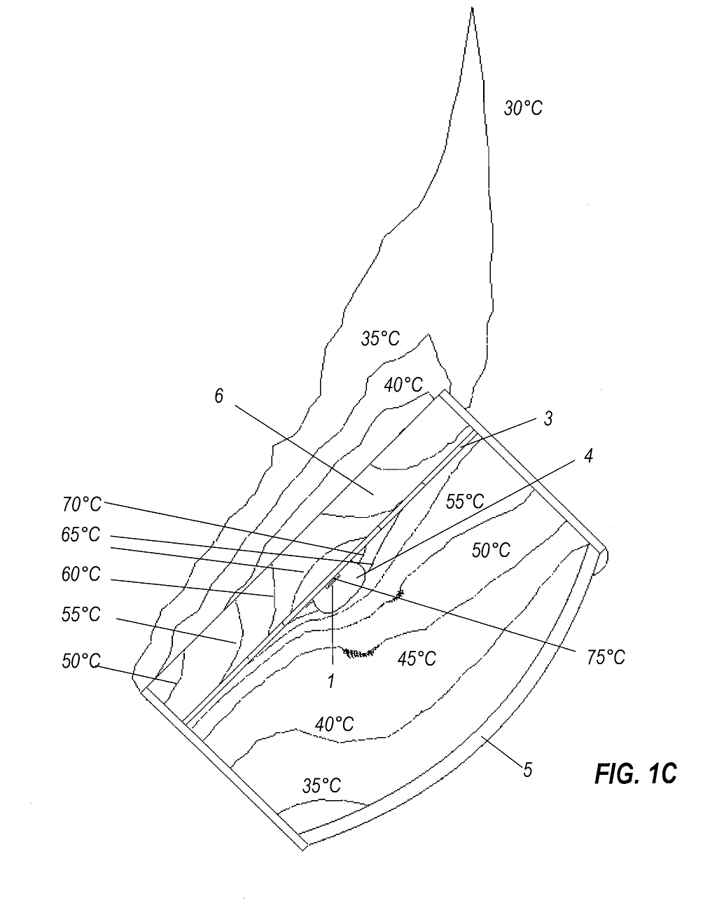

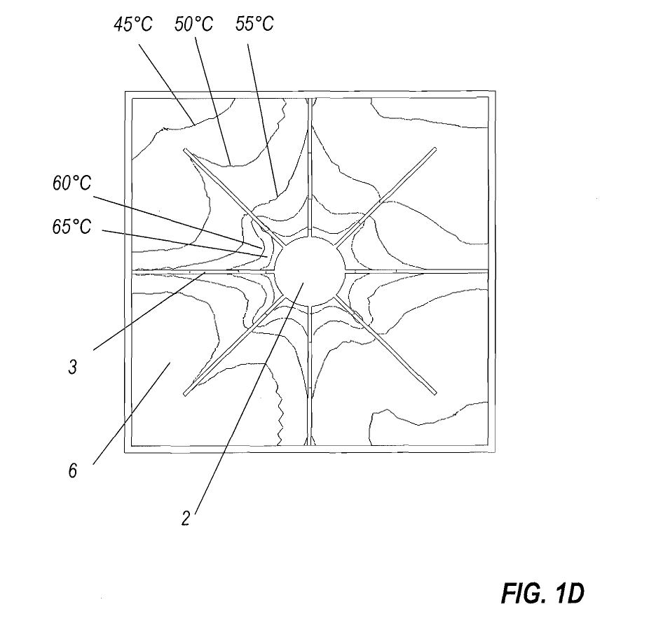

Referring initially to FIGS. 1A through 1D (collectively FIG. 1), FIG. 1A is an exploded view, and FIG. 1B an assembled view, of a first embodiment of a solar concentrator 10, comprising photovoltaic (PV) chip 1 mounted on a base 2, spreader bars or strips 3 radially extending from base 2, and secondary lens 4 covering PV chip 1. Base 2, with spreader bars 3, PV chip 1, and secondary lens 4, is mounted on the inside of cover glass 6, which is faced by primary reflector 5. In an example, primary reflector 5 is 50 mm on a side, and secondary lens 4 is 10 mm in diameter. Primary reflector 5 receives incoming direct solar rays 7 through cover glass 6, and concentrates the rays upon secondary lens 4, which in turns concentrates them upon chip 1, which is 2.24 mm on a side. Spreader bars 3 are 0.5 mm wide. Base 2 and spreader bars 3 have a depth of 0.6 mm and are made of copper (or some other material with suitably high conductivity).

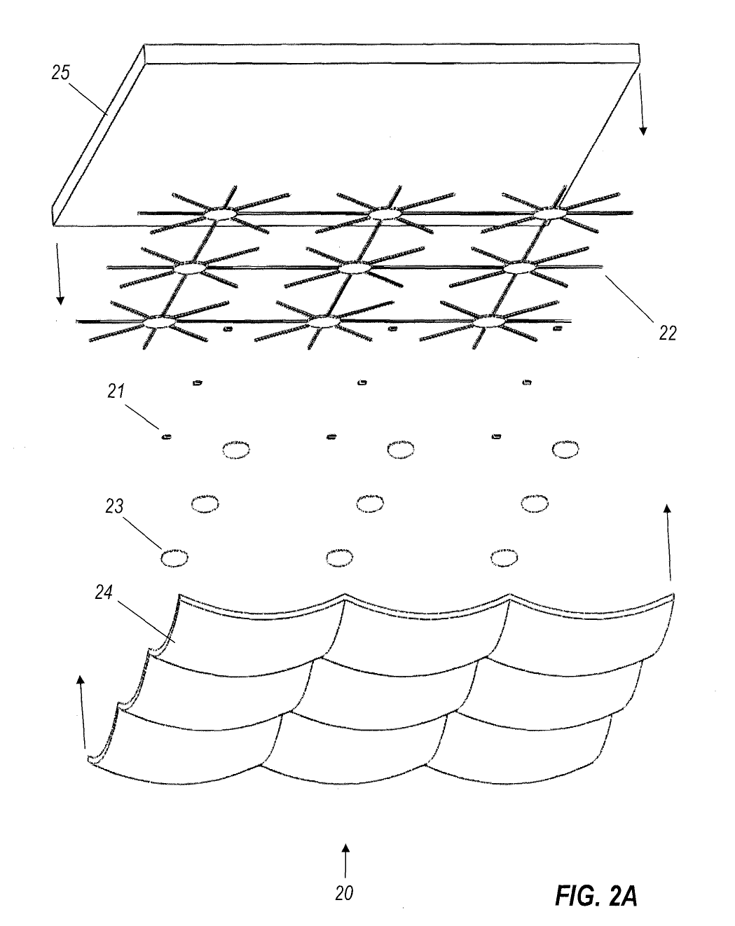

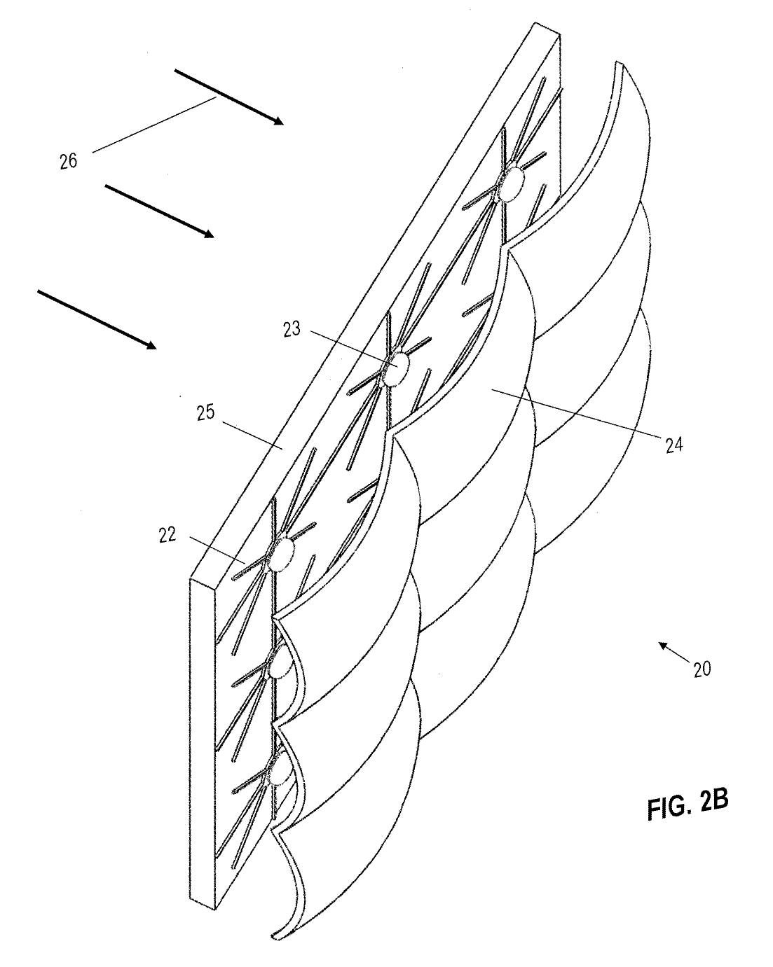

In FIG. 1B, and in similar assembled views of other embodiments (see FIGS. 2B, 3B, 4B, 4C, 5B, 6A, 6B, and 7 to 12), side walls, structural supports, and electrical connections are omitted in the interests of clarity and simplicity. Those components may be conventional, and can be provided from the ordinary knowledge of the skilled reader.

In spite of the fierce concentration (geometrical concentration 500 suns) onto chip 1 of all of rays 7 falling upon much larger cover 6, a cell delta temperature only 50° C. above ambient can be achieved. This is based on several factors: the solar radiation at the location is 850 W/m², the optical efficiency is 80%, the PV cell efficiency is 31% (a conservative figure), and the cover 6 is common glass 6 mm thick. In that implementation of the above example, only 1.175 W of heat must be dissipated from the cover 6. This is a direct benefit of the relatively small size of this system, which encourages arraying.

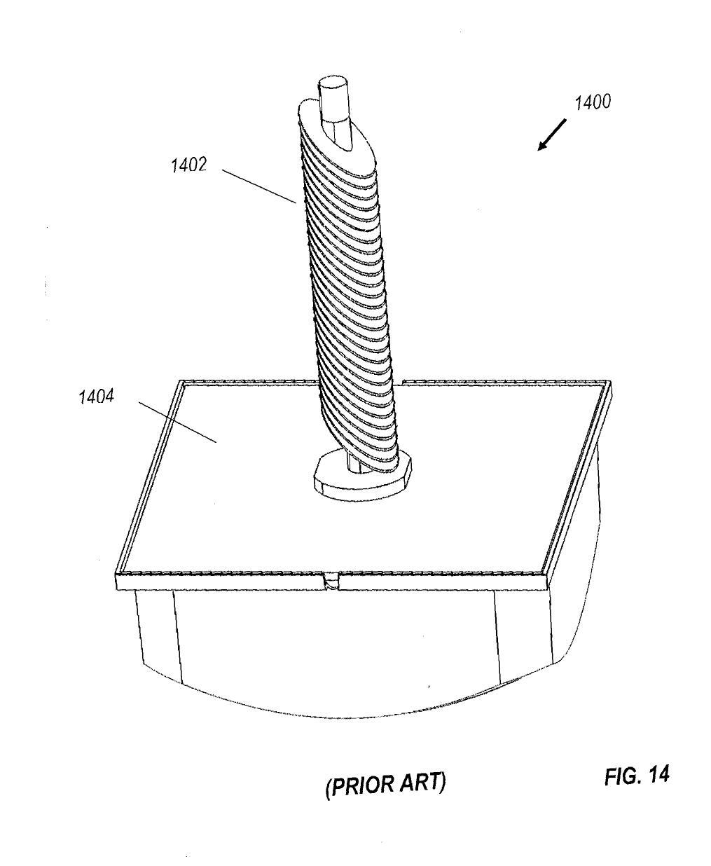

In this case the percent obstruction of the system is only 7%, which compares well with the 5% of the prior art of FIG. 14 (with its more complex, larger, and more expensive heat sink). The spreader bars 3 shown in FIG. 1 have eight-fold radial symmetry, with four primary radial bars oriented 90° from each other and running the full length and width of cover glass 5, while the remaining four secondary spreader bars are of the same length but rotated 45° relative to the primary. The primary spreader bars can be used as electrical vias between adjacent cells, and/or from peripheral cells to the exterior, and/or as electrical connections with the spreader bars of adjacent cells, or with an external frame. Other arrangements, including other n-fold symmetries and more complex planar tessellations can be utilized for the spreader bars. For example, the secondary spreader bars could be longer than the primary spreader bars, to reach further into the corners of the cover 6.

FIG. 1C shows a contour plot of the temperature gradient in the system for the above case when the ambient air is at 25° C., and there is no wind over the cover. The tilt of the panel is set at 45° to the ground, although this would vary both daily and seasonally. The simulations by the software package COSMOS fully modeled convection, radiation and conduction effects. It was assumed that the primary mirror had a low emissivity (0.05) coating on it facing the secondary optic, that the back surface of the concentrator 10 had an emissivity of 0.95 (that of black plastic), and that the side walls are adiabatic. The values of the temperature contour lines range from 30° C. (just above the ambient air temperature) to a maximum of 75° C., at the PV cell. FIG. 1C shows the relationship of the temperature contour lines with respect to photovoltaic chip 1, spreader bars 3, secondary lens 4, primary reflector 5 and cover glass 6, shown in cross-section.

The inventors' calculations show that in a typical scenario approximately 36% of the heat dissipation is infrared radiation from the cover glass 6, with the remainder of the heat dissipation being by conduction to and convection by the air in front of the cover glass.

FIG. 1D shows a perspective cutaway temperature contour-line plot looking from primary reflector 5 towards cover 6 and showing base 2 and spreader bars 3. The temperature gradient contour lines go from 45° C. to 70° C. in 5° intervals. The maximum temperature is 75° C. at photovoltaic chip 1 (see FIGS. 1A and 1C).

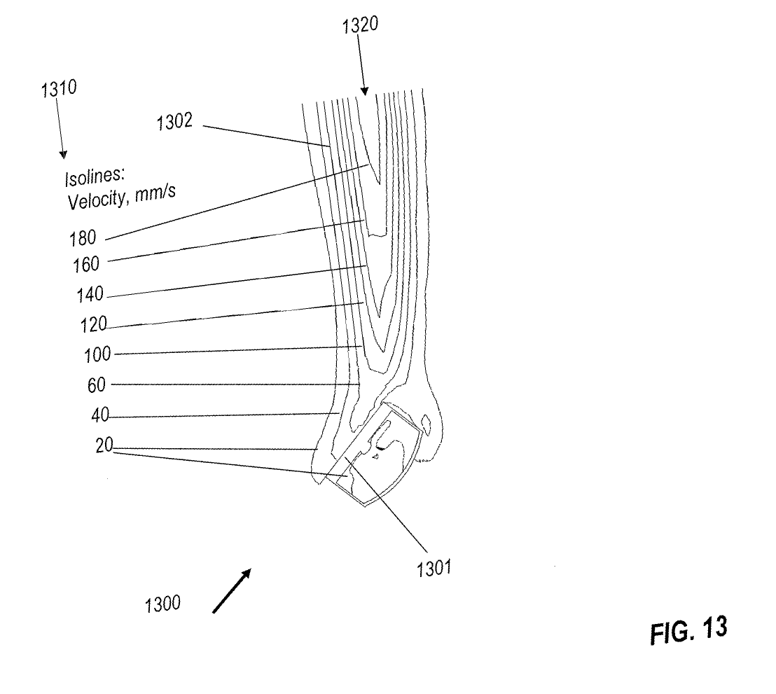

In FIGS. 1A and 1B, the sides of concentrator 10 are shown open. In FIGS. 1C and 1D side walls are shown. When a side wall separates two identical cells 10, and is reflective so that any glancing rays striking the side wall are reflected back onto the primary mirror 5, there is very little difference in performance between the two configurations. Side walls improve strength and rigidity, but make construction more complex, and reduce convection within the cells by preventing larger-scale convective air flows over several cells, but as will be explained below with reference to FIG. 13, convection within the cell is not strong.

As described above, the device 10 is a solar concentrator, in which the element 1 is a photovoltaic cell. The element 1 could instead be some other optoelectronic device, for example, a light-emitting diode or a semiconductor laser. The device 10 would then act with the light rays travelling in the opposite direction as a luminaire emitting a highly collimated beam of light. The skilled reader will understand that other applications for the device 10, both collimating and concentrating, are possible.

FIGS. 2A and 2B (collectively FIG. 2) show an array of the concentrators of FIG. 1, mounted on a large, continuous, sheet of glass 25 as cover sheet. The sheet 25 shown may be part of an even larger sheet of glass. FIG. 2A is an exploded view of array 20, comprising solar cells 21, heat-spreader assemblies 22, secondary lenses 23, primary reflectors 24 (also formed as part of a corrugated sheet), and cover glass 25. The array 20, or a larger array of which the array 20 is only part, or a larger array comprising an array of arrays 20, may in operation be mounted in a tracking panel (not shown). The technology of two-dimensional tracking of arrays of PV cells for solar electric generation is well known, and in the interests of conciseness will not be further discussed herein.

As may be seen in FIG. 2A, the long arms of the heat spreaders 3 are continuous across the boundaries between individual concentrators, so that assembly 22 forms a continuous grid of metal over the entire array, maintaining a uniform electrical ground potential and reducing any temperature differences between cells. The continuous arms may also provide electrical vias for wiring that electrically connects PV cells 21.

FIG. 2B shows array 20 assembled, with the same labels as in FIG. 2A except that cells 21 are hidden under secondary lenses 23. Also shown are direct solar rays 26, which primary mirror 24 focuses onto secondary lens 23, which in turn concentrates the rays upon the cells 21 within.

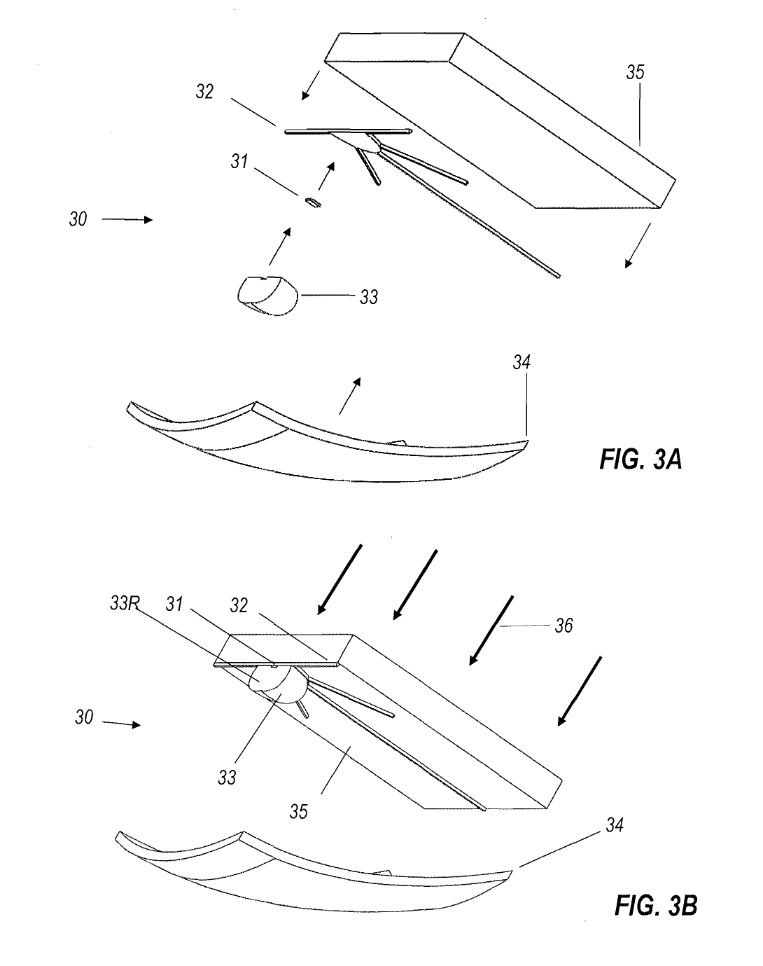

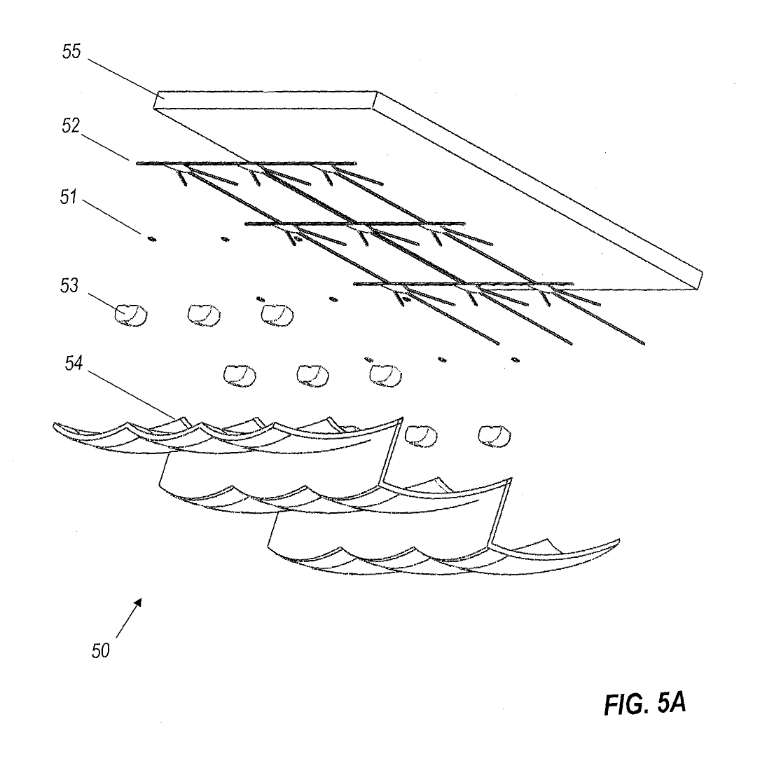

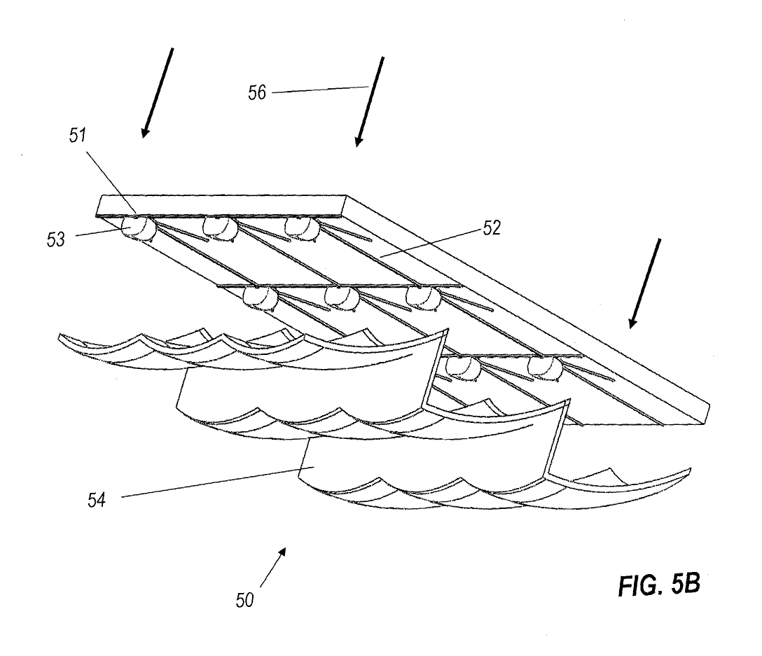

FIGS. 3A and 3B (collectively FIG. 3) show an asymmetric concentrator 30, comprising cell 31, heat spreader 32, secondary lens 33, primary mirror 34, and cover glass 35. It can be thought of as half of a rectangular concentrator. When secondary lens 33 has reflector 33R on its lateral face, the cell 31 can be half-sized, for double the concentration. The temperature gradient of this system is very similar to that of the symmetric XR embodiment of FIG. 1. The asymmetric spreader architecture is useful for such embodiments when arrayed as in FIG. 5, which can be called a saw-tooth configuration. In this case the arrangement of the spreaders on the end units is not rotationally symmetric.

While FIG. 3A is an exploded view of the asymmetric concentrator 30, FIG. 3B shows concentrator 30 assembled, with the same components shown, along with direct solar rays 36, which primary mirror 34 focuses onto secondary lens 33, which in turn concentrates them onto cell 31 within.

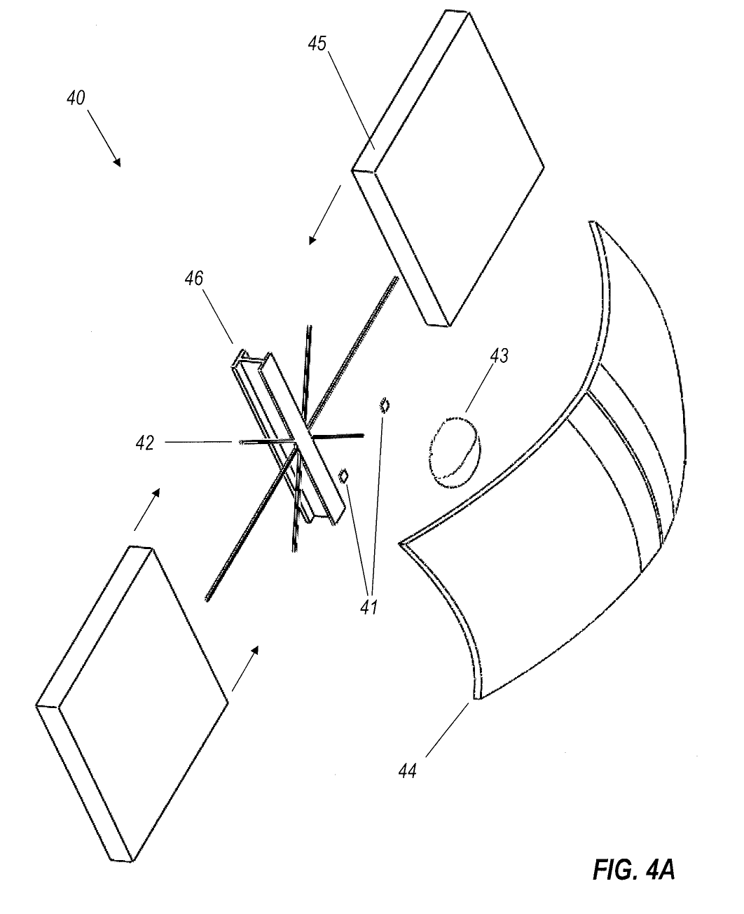

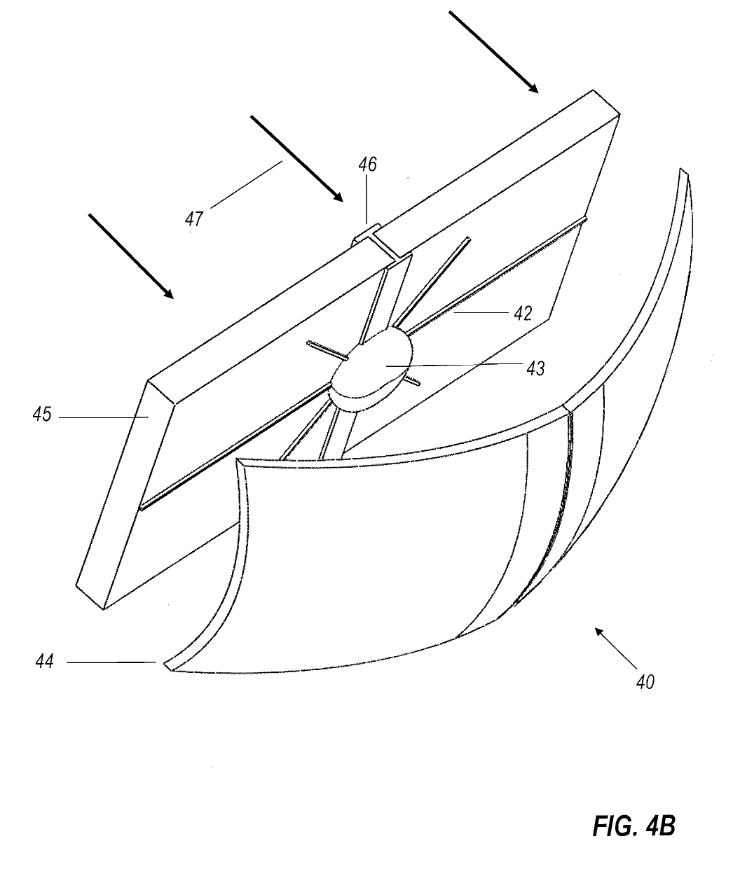

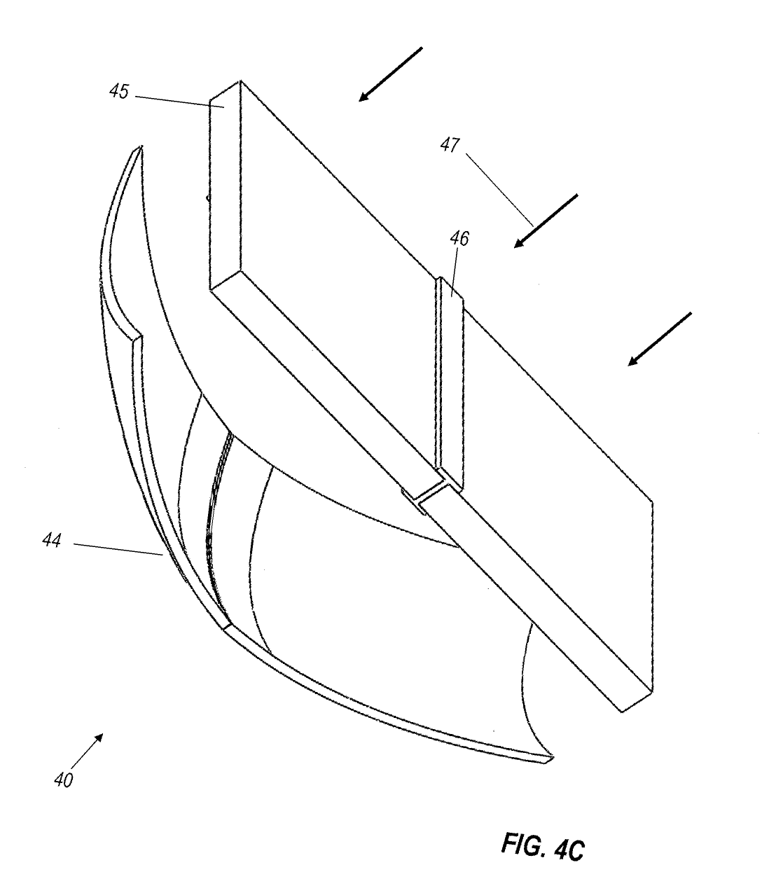

FIGS. 4A to 4C (collectively FIG. 4) show a dual concentrator 40, comprising two asymmetric concentrators akin to that of FIG. 3. Each single concentrator comprises one of two PV cells 41, heat spreader vanes 42, half of secondary lens 43, half of primary reflector 44, and its portion of cover glass 45. The two concentrators are mounted back to back with their PV cells 41 together.

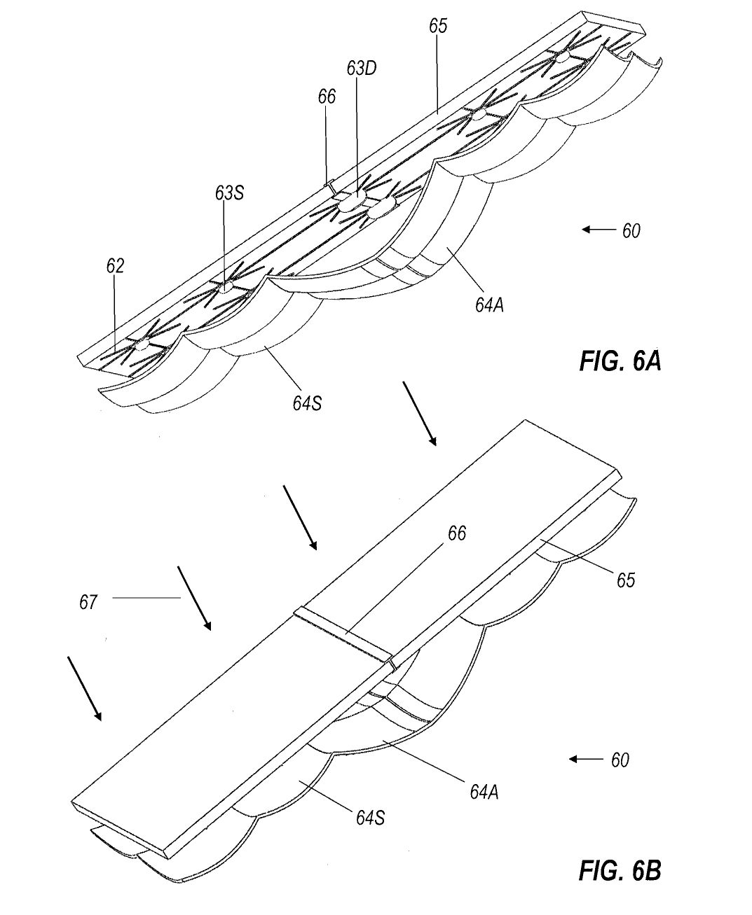

In FIG. 4A, I-beam 46 is part of a frame holding cover glass 45, and is metallic so as to comprise a primary heat remover for the cells 41, with which it is in close thermal contact. The thermal performance of this system is the same as the embodiment of FIG. 1 (the rotationally symmetric case) and that of FIG. 3, the asymmetric case, even though in the embodiment of FIG. 4, the energy density at the PV cells 41 is approximately two times higher. This is a consequence of the two cells 41 being mounted very close to each other. However, I-beam 46 can handle the higher thermal load twice as well as in the previously described embodiments, thus resulting in the same temperature at the PV cells as before. This is useful because the I-beam can be used to connect one glass cover to another in an array. Besides having the same temperature at the PV cells, the I-beam heat spreader configuration also blocks no more incident light than the previous embodiments. This makes it possible for hybrid systems such as the embodiment shown in FIG. 6 to work efficiently, since the temperatures of all the PV cells are the same, so that the photo current generation of all the cells is the same. Photocurrent equality is important, because an array of PV cells connected electrically in series runs at the lowest photocurrent of any cell in the series.

FIG. 4 also shows a join in the mirror 44, aligned with the I-beam 46. That enables modules, each consisting of an array of individual concentrators 10, 30 to be fabricated in a factory and then assembled into larger panels, by joining them at the I-beam 46 and the corresponding joint in mirror 44. The modules may be shipped to the installation site for assembly, if the full panels are inconveniently large for shipping. Alternatively, the panels may be assembled in the factory, if the full panels are shippable, but are too large for unitary fabrication with the available equipment.

While FIG. 4A shows an exploded view of concentrator 40, FIG. 4B shows concentrator 40 assembled, along with solar rays 47, which are concentrated by primary mirrors 44 onto secondary lenses 43. FIG. 4C is a similar view to FIG. 4B, but from above, also showing incoming solar rays 47.

FIGS. 5A and 5B (collectively FIG. 5) show an array 50 of multiple off-axis concentrators similar to concentrators 30 of FIG. 3. Array 50 comprises PV cells 51, heat spreaders 52, secondary lenses 53, multiple primary mirrors 54 in a single piece of material, and cover glass sheet 55. The temperature gradient of this system is similar to that shown in FIG. 1C and FIG. 1D.

FIG. 5A shows an exploded view of array 50. FIG. 5B shows array 50 as assembled, with incoming direct solar rays 56, which primary mirrors 54 concentrate onto secondary lenses 53, which in turn focus them onto cells 51. Primary mirrors 54 have walls between adjacent rows of concentrators, which in FIG. 5 are perpendicular to the cover glass 55. To increase the rigidity and strength of the array 50, the walls may be extended to reach the back of the glass.

FIGS. 6A and 6B (collectively FIG. 6) show a further combination of symmetric and asymmetric concentrators. FIG. 6A shows a photovoltaic array 60 from below and to one side, array 60 comprises heat spreaders 62, single-cell symmetric secondary lenses 63S, dual-cell secondary lenses 63D, symmetric primary reflectors 64S, asymmetric primary reflectors 64A, cover sheets 65, and thermally conducting I-beam 66. I-beam 66 can also be used as an element to structurally tie the upper components to the primary reflectors 64S. This requires, however, an additional vertical structural element (not shown) to be inserted and attached to I-beam 66 and primary reflectors 64S.

FIG. 6B shows a lateral view from above of the array 60, also showing incoming direct solar rays 67, which asymmetric primary reflectors 64A concentrate onto dual secondary lenses 63D, and symmetric primary reflectors 64S concentrate onto secondary lenses 63S.

The I-beam frame members 45 in FIGS. 4 and 65 in FIG. 6 depict the capability of the embodiments of the present invention to be assembled into highly populated arrays that fill a large panel, as for example when over six hundred 2″ (50 mm) square reflectors go into a 3 by 6 ft (900×1800 mm) panel.

The array 60 can then consist predominantly of concentrators similar to the concentrator 10 shown in FIG. 1, but with dual asymmetric concentrators similar to the concentrators 40 of FIG. 4, to take advantage of the I-beam frame members 45 at the joins between modules.

Given the closed environment of the concentrators disclosed herein, the interior air is expected to host only weak convection currents, at least in smaller versions. With the dimensions given above for FIG. 1, the space between the cover glass 6, etc. and the primary mirror 5, etc. is only about an inch (25 mm), which is too narrow for strong convection. This is shown by the velocity contours 1310 in FIG. 13, below. In larger versions, however, the air would be in convective motion, so it would be advantageous to augment the heat path to it from the cell.

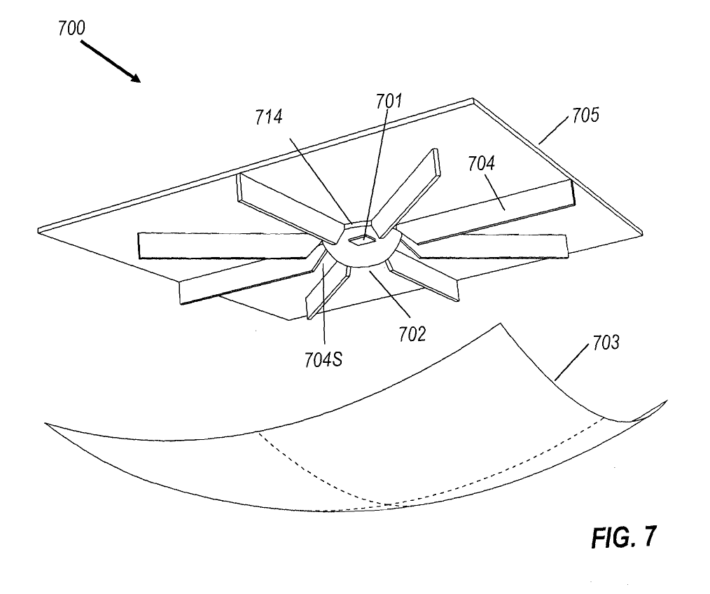

FIG. 7 shows another embodiment, reflective concentrator 700, comprising photovoltaic cell 701, secondary lens 702, primary mirror 703, fins 704, and cover glass 705. The fins 704 extend vertically (perpendicular to the cover glass) and, therefore, have a larger surface, increasing heat conductance. In this case the fins can also be made of a material less costly than copper, since a little extra height will make up for any resulting reduction in conductivity. Their greater contact area with air may also increases internal convection, although they would also tend to act as baffles that hinder convection. Also however, they could advantageously act to stiffen the cover glass 705. Fins 704 have slant-cut ends 704S where they join the base 714, on which PV cell 701 is mounted. The slant-cut ends 704S reduce the obstruction of the reflected sunlight incoming from primary mirror 703.

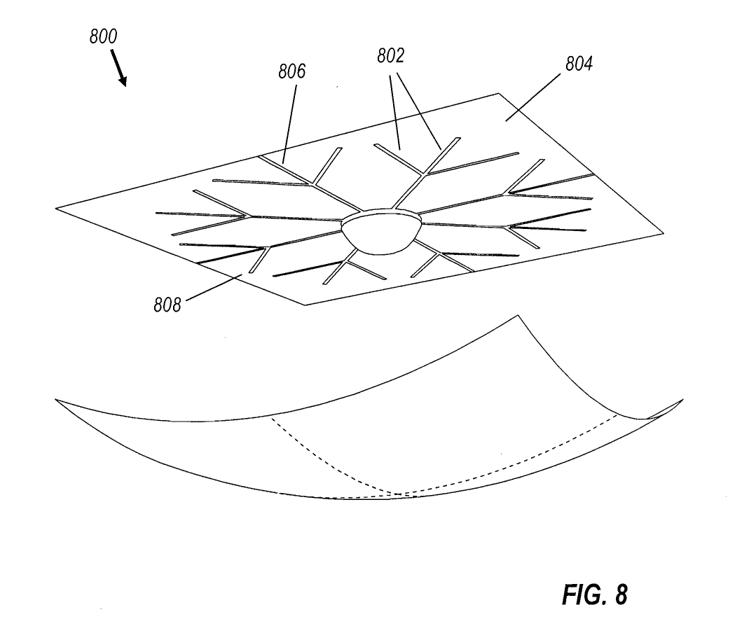

FIG. 8 shows a device 800 similar to the concentrator 10 of FIG. 1, except that the conductive strips or bars 802 now have a tree-like structure. These strips may also be fins extending perpendicular to the glass cover 804, as did fins 704 in FIG. 7. To enhance heat conduction but minimize shadowing, the radial conductive elements 806 may be deep fins 704, and the oblique elements 808 may be thin strips. This new fin structure spreads out the heat more evenly over the glass cover 804. In general, the goal is to minimize the distance from any point on the glass cover to the metal spreaders 802. That evens out the temperature over the entire glass cover, improving heat transfer to air and lowering the temperature of the glass and metal closer to the PV cell, which thereby runs cooler.

As is shown in the embodiment of FIG. 3, the spreader bars need not have rotational symmetry. If they do, however, the full n-fold symmetry of n arms is not required. Also, they do not have to be straight. For example, a fractal arrangement can also work which uses tree-like (larger branches originate many smaller ones) 2-D tessellations. Finally, the depth of some or all of the spreaders can be increased to improve thermal conductivity and uniformity of the temperature gradient through the components, in order to mitigate the potential for the spreaders to delaminate from the glass cover or even to break the glass cover. One skilled in the art of thermal engineering would be able to arrive at numerous solutions once the principles taught in this application are fully understood.

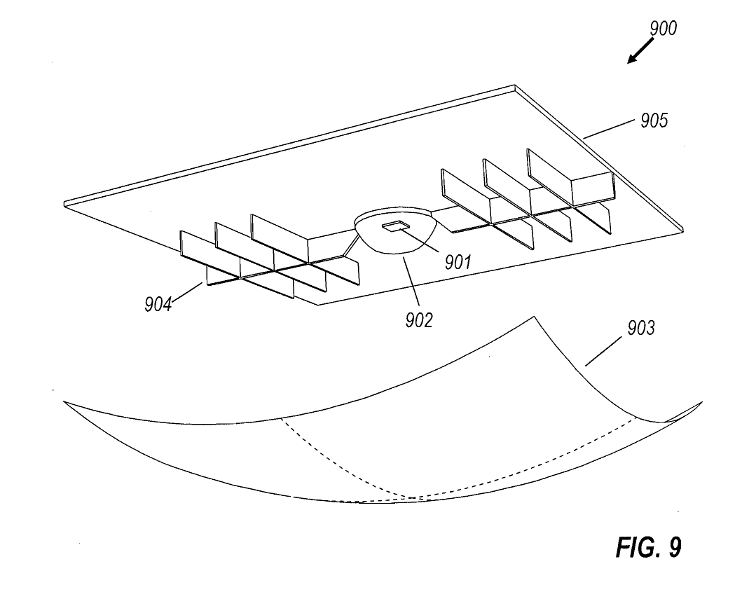

FIG. 9 shows another configuration in which the spreader bars have ramifications to improve heat distribution over the glass cover. Reflective concentrator 900 comprises photovoltaic cell 901, secondary lens 902, primary mirror 903, fins 904, and cover glass 905. As with FIG. 8, the transverse fins 904 in FIG. 9 may appreciably shadow the cell, especially the ones nearest the PV cell 902. It may therefore be beneficial to reduce the depth of those fins, especially at their tips. Because the individual concentrator 900 is rectangular, the primary mirror 903 is closest to the cover glass at its corners, so that reflected light approaches the PV cell 901 at a flatter minimum angle of incidence from the corners than from the middles of the sides.

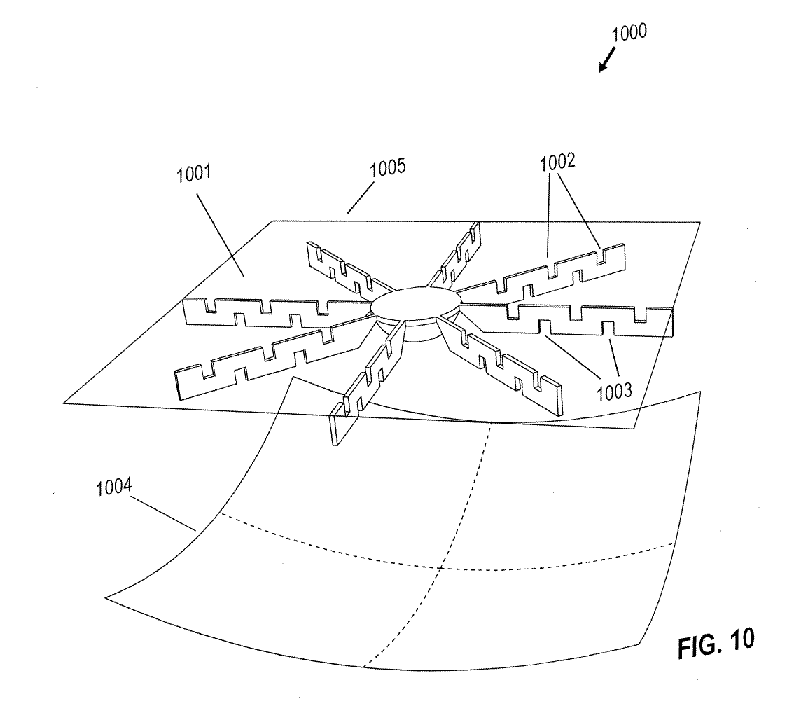

FIG. 10 shows reflective concentrator 1000, comprising fins 1001 with upper slots 1002 and lower slots 1003. These slots give the structure some flexibility as well as some capacity to adjust for differential expansion of metal and glass as they warm to normal operation.

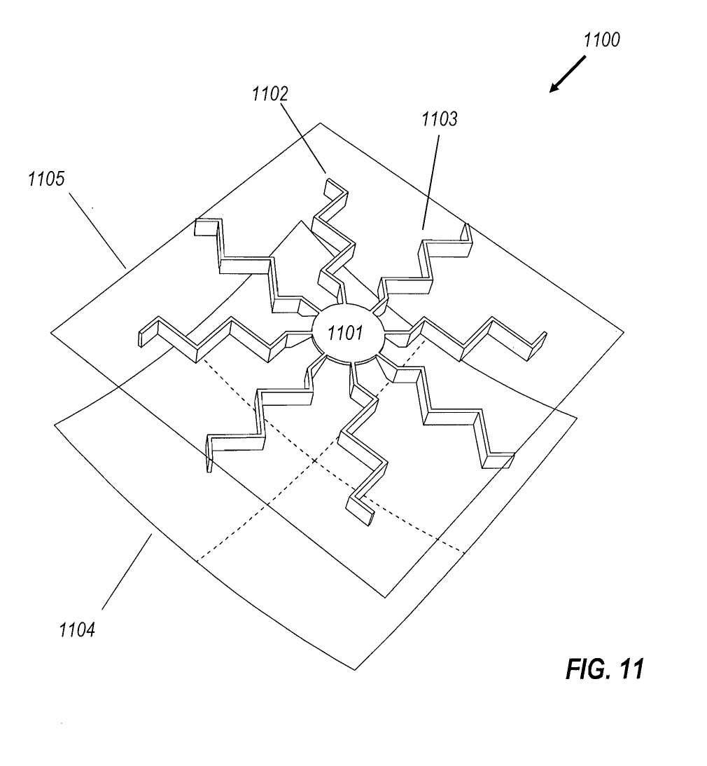

FIG. 11 shows a further reflective concentrator 1100, comprising primary mirror 1104, cover glass 1105, central base or heat plate 1101, and fins 1102 with saw-tooth or zigzag corners 1103.

In the case of FIG. 7, the thermal expansion of copper (greater than that of glass) could result in a relatively large movement of the tips of the copper strips relative to the glass. This is avoided in FIG. 11 by the zigzag geometry of the fins 1102, 1103. This zigzag shape keeps the expansion of each segment local (and much smaller as well), thus avoiding the radial buildup of thermal expansion of the different segments building up in the radial direction away from 1101. Also, this kind of fin provides a more uniform coverage of the glass cover, improving on the heat spreading uniformity. The uniformity can be further improved by increasing the amplitude of the zigzags further from the center.

These zigzag fins may also be given a tree-like structure as the one in FIG. 8, replacing the straight fins by zigzag ones.

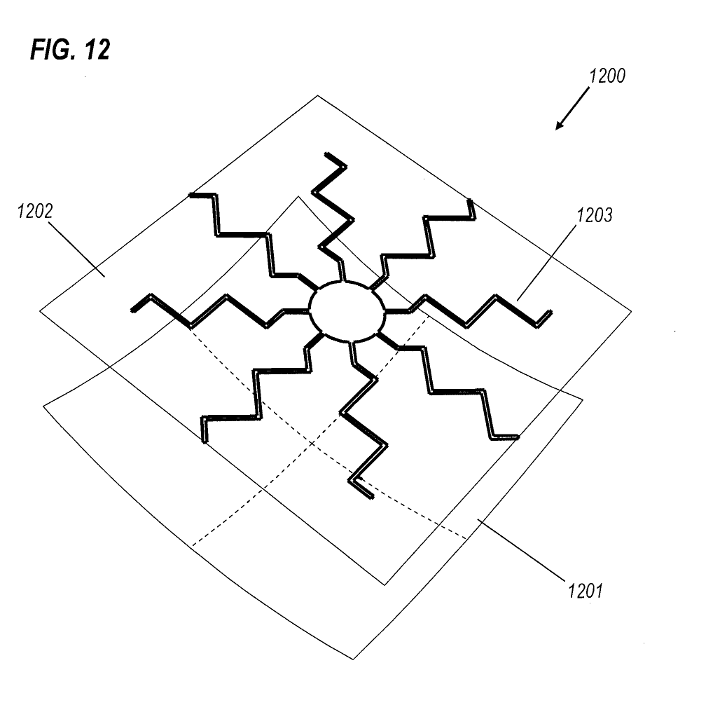

FIG. 12 shows a further reflective concentrator 1200, comprising primary mirror 1201, cover glass 1202, and radial zigzag fins 1203, with the same zigzag geometry as in FIG. 6, but with much smaller height of the fins (in the direction perpendicular to the glass cover), more similar to FIG. 1. This may be advantageous when the spreading of heat is limited much more by the conductance of the glass than by that of the metal, so that long, thin metal strips can be accepted in order to achieve shorter distances over the glass. This is an example of how features of different embodiments can be combined and substituted to provide still further advantageous embodiments and fulfill specific requirements.

FIG. 13 shows an air flow speed map 1300, for a concentrator 1301 (shown in cross-section) similar to the concentrator 10 of FIG. 1. The velocity contours 1302 are coded by legend 1310, listing values of speed in mm/s. Within the concentrator, the air speed is 20 mm/second or less near the cover glass, increasing to around 40 mm/s near the bottom of the concentrator. The low air speed confirms that there is not much convection within the concentrator, and little heat is transferred to the primary mirror. Speeds outside the concentrator 1301 are around 20 mm/s below the concentrator and 40 mm/s over the upward-facing surfaces, rising to nearer 80 mm/s at the top corner. Above the concentrator 1301 there is a plume-acceleration effect, leading to vertical velocities up to 200 mm/s in a small zone 1320 at the center of the upward stream.

FIG. 14 shows prior-art reflective concentrator 1400, comprising a conventional heat sink 1402 projecting forward from cover glass 1404. The heat sink 1402 is highly vulnerable to impact damage and to clogging by dust and dirt. Also, it will obstruct the cleaning of cover glass 1404, especially in the case of large arrays.

The stack of metal fins 1402 may be bonded to the glass cover using a flexible, thermally conducting adhesive. Suitable adhesives are widely available. Examples of thermally conductive, electrically insulating adhesives with high flexibility and elongation may be found at: http[colon]//www.masterbond[dot]com/sg/masterbond_tcsg[dot]pdf, and at http[colon]//solutions[dot]3 m[dot]com/. See, for example, 3M Thermally Conductive Adhesive Transfer Tape 9882, which is a 2.0 mil (0.05 mm) thermally conductive adhesive transfer tape for mounting flexible heating foils, temperature indicating films, and thermoelectric cooling modules, as well as bonding flexible circuits to heat sinks. See, for example, 3M Thermally Conductive Adhesive Transfer Tape 9885, which is a 5.0 mil (0.13 mm) thermally conductive adhesive transfer tape, for mounting thermoelectric cooling modules, bonding flexible circuits to heat sinks, bonding heat sinks to microprocessors, and bonding TAB-mounted ICs to PCB.

The preceding description of the presently contemplated best mode of practicing the invention is not to be taken in a limiting sense, but is made merely for the purpose of describing the general principles of the invention. Variations are possible from the specific embodiments described. For example, the patents and applications cross-referenced above describe systems and methods that may advantageously be combined with the teachings of the present application. Although specific embodiments have been described, the skilled person will understand how features of different embodiments may be combined.

All of the embodiments have been described with a flat cover glass, having the heat spreader attached to the inside face. That is strongly preferred, because a smooth, flat exterior surface that is uninterrupted (except perhaps for the I-beams 46, 66 or other such framing) allows for easy cleaning of the outside of the cover glass. That is important in a concentrating solar photovoltaic device, because the sunlight that dust scatters is lost to concentration, reducing the efficiency of the device. Although a cover “glass” has been described, other transparent materials could of course be used. However, glass is cheap, hard, and widely obtainable in large, smooth, flat sheets, with well known properties and familiar handling characteristics. Glass is therefore presently preferred in most applications.

In the described embodiments, each concentrator has a unitary primary mirror and a unitary secondary lens. Other configurations are possible. For example, the skilled person will understand how to apply certain of the principles of the above mentioned US 2010/0123954. That application describes concentrators in which primary and secondary optical elements each comprise several facets that concentrate light onto a single PV cell. The subdivisions shown on the secondary lens in FIGS. 3-5 and on the primary mirror in FIGS. 7-12 of the present application may be interpreted as symbolizing a similar subdivision of the optical surfaces.

The goal of the conducting strips of the heat spreader disclosed herein is to uniformly spread the heat generated within the cell over a large glass cover. This has some parallel with what happens in solar cells, only the other way around. Within a cell, electron-hole pairs are generated uniformly throughout the cell, but in order to generate power they must be collected, typically by a metallization grid. Due to the very small width of the elements in the metallization grid and the consequent precise alignment they would require, it would be difficult to produce on a cell the same kind of strips as shown in the Figures. With success, however, it would theoretically possible for the thermal strips on the cover plate to be imaged onto the metallization strips on the cell by lenslets disposed between the heat-spreader strips. Such an option for a concentrator would be, for example, a Köhler concentrator with a smooth mirror.

FIG. 9 can illustrate this concept, with grid-like heat spreader 904, with optical elements (lenslets too imperceptibly curved to be discernible) on the inside surface of the glass cover 905. Such elements image (through the mirror) the system acceptance angle (typically over ±1°) onto the dielectric secondary optical elements covering the solar cell (again, too small to be shown) between the metallization strips. The dielectric secondary optical element would image (through the mirror) the lenslets on the cover glass onto those on the solar cell. This secondary optical element would also image the heat-spreader strips on the glass cover onto the solar cell. If the strip pattern on the cover and the metallization grid on the cell are an image of each other (their patterns match), the shadow cast by the strips would be imaged onto the metallization grid, which is not active. This would effectively eliminate the losses produced by the strips under the glass cover, albeit at the marginal cost of extra precision of the cell metallization grid.

Where lenslets or other optically active surfaces are formed on the glass cover, it is usually preferable to form such surfaces on the inside of the cover, between the metallization strips. Then, the outside of the cover can still be smooth, and usually flat, for ease of cleaning.

The full scope of the invention should be determined with reference to the Claims.

We claim:

1. An optoelectrical device comprising:
a transparent cover plate;
a target comprising an optoelectrical transducer mounted at an inside face of said transparent cover plate, said target producing waste heat in operation;
a primary mirror arranged to reflect light between being concentrated on said target and passing generally collimated through said cover plate; and
a heat spreader in thermal contact with said target, said heat spreader comprising heat conductors that thermally connect said target with said inside surface of said cover plate.

2. The device of claim 1, wherein said target further comprises a secondary lens disposed between said primary mirror and said optoelectrical transducer.

3. The device of claim 1, wherein said optoelectrical transducer comprises a multi-junction photovoltaic cell.

4. The device of claim 1, wherein said heat spreader is attached to said inside face of said transparent cover plate.

5. The device of claim 1, wherein said heat conductors comprise spokes extending outward from said target.

6. The device of claim 5, wherein at least parts of said spokes are taller in a direction away from said cover plate than their width in a direction transverse to their length and parallel to said cover plate.

7. The device of claim 6, wherein at least some of said spokes have a height extending from said cover plate all the way to said primary mirror.

8. The device of claim 5, wherein said spokes zigzag over said inside surface of said cover plate.

9. The device of claim 5, wherein said spokes comprise branches that articulate outward from said target.

10. The device of claim 5, wherein at least one of said spokes extends to an edge of the device, and forms a via for an electrical connection to said optoelectrical transducer.

11. The device of claim 5, wherein said spokes block less than 10% of the light passing through said cover plate to or from said optoelectrical transducer.

12. The device of claim 11, wherein said spokes block less than 7% of the light passing through said cover plate to or from said optoelectrical transducer.

13. The device of claim 12, wherein said spokes block less than 5% of the light passing through said cover plate to or from said transducer.

14. An optoelectrical array comprising:
a common transparent cover plate; and
a plurality of optoelectrical devices, each said device comprising:
a target comprising an optoelectrical transducer mounted at an inside face of said transparent cover plate;
a primary mirror arranged to reflect light between being concentrated on said target and passing generally collimated through said cover plate; and
a heat spreader in thermal contact with said optoelectrical transducer, said heat spreader comprising outwardly extending thermally conductive arms disposed between said primary mirror and said cover plate and in thermal contact with said cover plate.

15. The array of claim 14, wherein at least some of said arms are continuous between adjacent optoelectrical devices.

16. The array of claim 15, wherein said continuous arms are electrically conductive, and form a network of common electrical potential connecting said optoelectrical devices.

17. The array of claim 15, wherein said continuous arms form vias containing electrical connections between said optoelectrical transducers of different said optoelectrical devices.

18. The array of claim 14, wherein at least one said target is mounted on an opaque support at an edge of said transparent cover plate, said support forming part of said heat spreader.

19. The array of claim 18, comprising two said common transparent cover plates, wherein said support joins and supports said two cover plates.

20. A solar concentrator comprising concentration optics, a target, a transparent cover, and a heat spreader, said heat spreader comprising a base in thermal contact with said target and multiple spokes extending radially therefrom, the material of said heat spreader having high thermal conductivity, said heat spreader in thermal contact with said transparent cover.
